(19) United States
(12) Patent Application Publication
(10) Pub. No.: US 2007/0190670 A1
(43) Pub. Date: Aug. 16, 2007

(54) Method of making ferroelectric and dielectric layered superlattice materials and memories utilizing same

(76) Inventor: Carl A. Forest, Denver, CO (US)

Correspondence Address: PATTON BOGGS LLP, 1801 CALFORNIA STREET, SUITE 4900, DENVER, CO, 80202, US

(21) Appl. No.: 11/704,623

(22) Filed: Feb. 9, 2007

Related U.S. Application Data
(60) Provisional application No. 60/772,174, filed on Feb. 10, 2006.

(51) Int. Cl. H01L 21/00

(52) U.S. Cl. 438/3; 257/E27.086

(57) ABSTRACT

A method of making a ferroelectric integrated circuit comprising: depositing a thin film of a layered superlattice material using atomic layer deposition (ALD); and completing the integrated circuit. The layered superlattice material is a ferroelectric material or a dielectric material. The method further comprises annealing the thin film using a short RTP process.

### CROSS REFERENCE

This invention is related to U.S. Provisional Application Ser. No. 60/772,174 filed Feb. 10, 2006.

### BACKGROUND OF THE INVENTION

1. Field of the Invention

The invention in general relates to ferroelectric memories, more particularly to a method of making such memories and, more particularly, the ferroelectric layered superlattice material in such memories.

2. Statement of the Problem

Ferroelectric memories have been known for more than fifty years. Many large corporations invested significantly in research on such memories before giving up. See, Orlando Auciello et al, “The Physics of Ferroelectric Memories”, Physics Today, Vol. 51, Number 7, July 1998 pp. 22-27. One line of research into ferroelectric memories focused on what generally are referred to as ABO₃ type materials, primarily PZT and related materials. These materials are solid solutions of simple oxides. The reason research focused on these materials was that, in the bulk, they had the highest polarizabilities of any ferroelectric. In addition, they could be fabricated at relatively low temperatures. However, except for a few nitch applications, commercially useful memories have never been made with these materials. The key problem that could not be solved was ferroelectric fatigue; that is, as the memories were switched, the ferroelectric polarizability in the memories quickly declined below a value at which the memory would work. This was due to defects which migrated to the surface and caused a polarization charge to form on the surface which cancelled any applied electric field. In addition, as the ABO₃ ferroelectric materials were made thinner, the ferroelectric polarizability declined significantly. See, I. P. Batra, P. Wurfel, and B. D. Silverman, Phase Transition, Stability, and Depolarization Field In Ferroelectric Thin Films, Physical Review, Vol. 8, No. 7, 1 Oct. 1973, pp. 3257-3265. Those skilled in the art believed that commercially dense ferroelectric memories could not be made.

However, these problems were dramatically solved in 1991 by a group at Symetrix Corporation led by Carlos A. Paz De Araujo by utilizing a class of materials that were essentially curiosities never before successfully utilized in ferroelectric applications. See U.S. Pat. No. 5,519,234 issued May 21, 1996 to Carlos A. Paz De Araujo et al. These materials, which spontaneously form themselves into distinct layers, were found to have much better polarizability in thin film form than they did in bulk form, and further, the polarizability did not fatigue within normal memory lifetimes. The present inventor recognized that these layered materials were natural superlattices, and called them layered superlattice materials.

There were still many problems to be solved before ferroelectric materials could be commercialized. The early layered superlattice materials required temperatures of about 800° C. to crystallize, which was higher than conventional integrated circuit materials could tolerate; further it was difficult to make electronic quality films thinner than about 100 nanometers. In addition, the layered materials were not compatible with silicon, since silicon required a backend hydrogen reduction process to maintain suitable semiconducting properties, and the layered materials were oxides that were damaged by the hydrogen reduction process. Since 1991 these problems have all been solved, primarily by the Araujo/McMillan group at Symetrix Corporation and by research teams at Matsushita Electrical Industrial Company, Ltd. See, for example, U.S. Pat. No. 6,104,049 issued Aug. 15, 2000 to Solayappan et al. and U.S. Pat. No. 6,815,223 issued Nov. 9, 2004 to Jolanta Celinska et al. Millions of commercial ferroelectric memories are now being made for particular applications, such as smart cards, particularly by Matsushita Electrical Industrial Company, Ltd.

State of the art ferroelectric non-volatile memories are a thousand times faster and require ten thousand times less power than other non-volatile memories, such as flash memory. Yet, ferroelectric memories have not yet reached the memory main stream, largely because flash is much denser than ferroelectric. The primary problems that prevent ferroelectric memories from being made more dense are the requirements of: a relatively large ferroelectric capacitor and associated circuitry, and ferroelectric disturb. Disturb occurs when writing or reading to a one cell causes a small voltage to be applied to neighboring cells. The source of the disturb problem is again defects. The disturbs add up and eventually can cause loss of data. For this reason, it is necessary to isolate each cell from its neighbors to ensure memory stability. See U.S. Pat. No. 6,809,949 B2 issued Oct. 26, 2004 to lu-Meng Tom Ho. This requires additional circuitry, not necessary in flash and DRAM for example. This additional circuitry and the size of the ferroelectric capacitor adds to the footprint of a memory cell, and prevents ferroelectric memories from being made more dense. The requirements of a relatively large capacitor and the disturb problem exist for all ferroelectric materials, including the layered superlattice materials.

The fact that excess density remains the most significant remaining problem in the way of widespread commercial use of ferroelectric memories is somewhat ironic because the original incentive for research in ferroelectric memories was the promise of creating an extremely dense non-volatile memory. The original concept was a ferroelectric memory made in the following manner. A wiring layer including a plurality of horizontal rows of wires is deposited, and a ferroelectric material is deposited over the horizontal wires, and a wiring layer including a plurality of vertical columns of wires is deposited on the ferroelectric. This creates a memory cell at each point were one of the horizontal and vertical wires cross. Such a memory is generally called a “raw array”, because it is essentially the simplest array possible with no additional complexity. See U.S. Pat. No. 5,024,964 issued Jun. 18, 1991 to George A. Roher and Larry D. McMillan. The raw array is not only simple in structure, but, in principal, is also extremely simple to operate, assuming that the ferroelectric material has a sharply defined coercive voltage, where the coercive voltage is the voltage at which the ferroelectric material switches. Suppose the coercive voltage is 4.5 volts. Then, in principle, if a voltage of 2.5 volts is put on one of the horizontal wires and a voltage of −2.5 volts is put on one of the vertical wires, then where the wires cross, i.e., at the selected cell, the total voltage across the ferroelectric will be five volts, and the ferroelectric will switch. If all the other wires are at zero volts, then the voltage across any all the other cells in the selected row and column, will be 2.5 volts, and these cells will switch. The voltage across all cells in the non-selected rows and columns will be zero and they will not switch either. Thus, write process is extremely simple. As known in the art the read process of this ideal raw array is corresponding simple. However, the raw array never worked because a ferroelectric material with such a well-defined coercive voltage has never been available, and the non-selected cells with a voltage of 2.5 volts across them sometimes switch. This is called the “half-select” problem. The half-select problem is an especially serious example of the disturb problem that continues to be problematic in ferroelectric memories, except those with complex structures to isolate the non-selected cells from the selected cells.

A ferroelectric memory and process of making it which overcomes the disturb problem without complex electronic structures and results in denser ferroelectric memories would be highly desirable.

### SUMMARY OF THE INVENTION

The invention provides a solution to the above problem by providing a process of making a ferroelectric integrated circuit that includes ferroelectric layered superlattice material, in which both the non-ferroelectric portions of the circuit and the ferroelectric portions of the circuit have greatly improved quality.

The invention provides a method of making a ferroelectric integrated circuit, the method comprising: depositing a thin film of a layered superlattice material using atomic layer deposition (ALD); and completing the integrated circuit to include the thin film in an integrated circuit component. The layered superlattice material is a ferroelectric material or a dielectric material. Preferably, the method further comprises annealing the thin film using an RTP process. Preferably, the RTP process is performed at a temperature of between 500° C. and 800° C. for a time period of from 0.5 seconds to 5 minutes. More preferably the RTP process is performed at a temperature between 550° C. and 700° C. for 1 second to 30 seconds. Preferably, the RTP process is performed with a ramping rate of between 50° C. per second and 200° C. per second. More preferably, the RTP process is performed with a ramping rate of between 90° C. per second and 150° C. per second. Preferably, the ALD process is performed with a plurality of alternating oxygen and hydrogen cycle portions, with each the cycle portions being of a length of 5 seconds or less. Preferably, each of the plurality of cycle portions is of a length of one second or less. Preferably, the ALD process is performed at a temperature of 150° C. or less. Preferably, the oxygen cycle portions are performed at a temperature of 150° C. or less and the hydrogen cycles are performed at a temperature of 100° C. or less.

The invention makes available ferroelectric memories of greatly simplified design. Numerous other features, objects and advantages of the invention will become apparent from the following description when read in conjunction with the accompanying drawing.

### BRIEF DESCRIPTION OF THE DRAWING

FIG. 1 illustrates a portion of a ferroelectric raw array employed in an exemplary embodiment of a ferroelectric memory according to the invention;

FIG. 2 shows a circuit diagram of another exemplary embodiment of a ferroelectric memory according to the invention in which diodes are added to the raw array of FIG. 1;

FIG. 3 shows a memory cell for another exemplary embodiment of a ferroelectric memory according to the invention;

FIG. 4 shows a ferroelectric FET which forms a memory element for another exemplary embodiment of a ferroelectric memory according to the invention;

FIG. 5 is a block diagram of the electronics of an exemplary ferroelectric memory which may be employed with any of the memories of FIGS. 1-4;

FIG. 6 shows the crystal structure of a ferroelectric layered superlattice material having the formula ABi₂B₂⁺⁵O₉;

FIG. 7 shows the crystal structure of a ferroelectric layered superlattice material having the formula ABi₂B₄⁺⁴O₁₅;

FIG. 8 is a flow diagram illustrating the process of making a ferroelectric integrated circuit capacitor according to the invention;

FIG. 9 is a top view of an exemplary wafer on which thin film capacitors fabricated in accordance with the invention are shown greatly enlarged; and

FIG. 10 is a portion of a cross-section of FIG. 9 taken through the line 10-10, illustrating an exemplary thin film capacitor fabricated in accordance with the invention.

### DETAILED DESCRIPTION OF THE PREFERRED EMBODIMENT

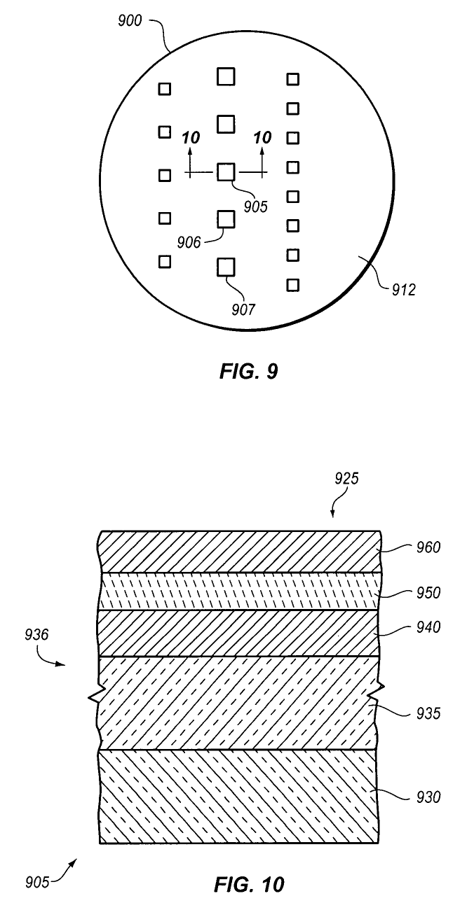

According to the invention, layered superlattice ferroelectric and dielectric materials are made using an atomic layer deposition (ALD) process (FIG. 9). The preferred ALD deposition system is described in U.S. Pat. No. 6,911,092, which is hereby incorporated by reference to the same extent as though fully disclosed herein. In this process, the ALD precursors are pulse using a pressurized booster chamber to input the precursors and a draw chamber capable of high draw to remove the precursors, in combination with fast-acting valves. This makes the ALD cycles extremely short, generally less than 30 seconds, more preferably less than five seconds, and most preferably less than a second. However, any other ALD apparatus may also be used. The preferred application of the material made according to the invention is in ferroelectric memories. Prior to this disclosure, those skilled in the art have believed ALD to be too complex and too slow for commercial use in making ferroelectric layered superlattice materials and particularly such materials for ferroelectric memories. However, as shall be disclosed in more detail below, it has been discovered that ALD actually has an unexpected synergism with these ferroelectrics as applied in ferroelectric memories, which synergism permits these perceived disadvantages to be overcome.

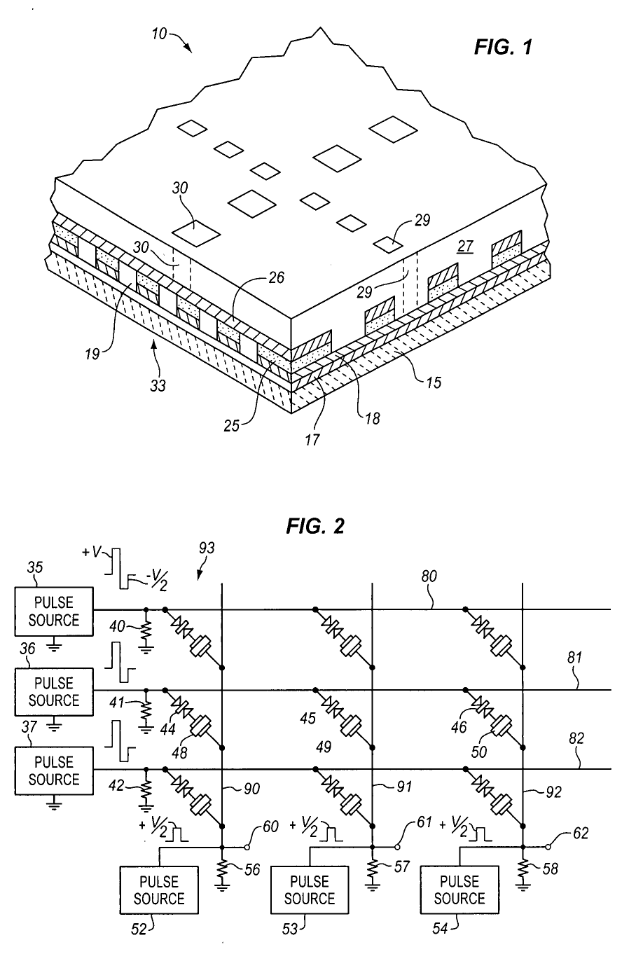

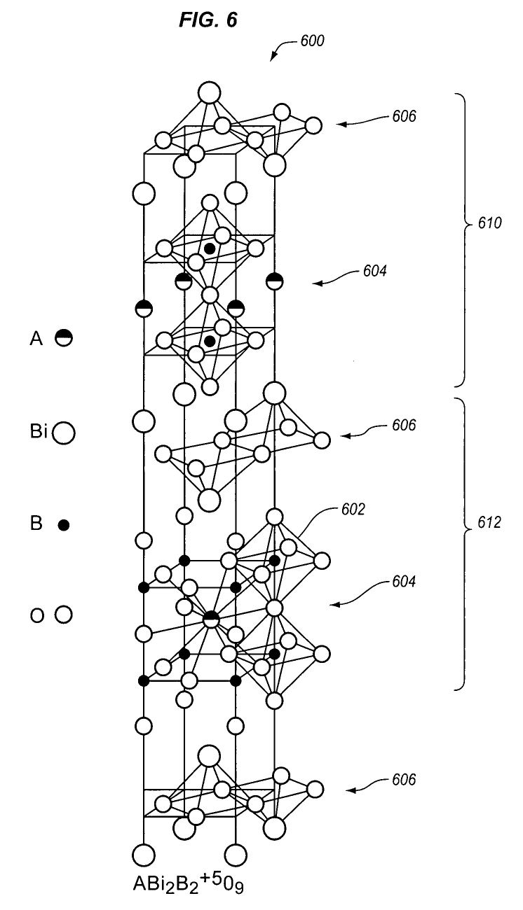

FIGS. 1 through 5 illustrate four exemplary ferroelectric memories into which the invention may be advantageously incorporated. However, it should be understood that these illustrations are not intended to be limiting. The invention may be applied to any ferroelectric memory, though it is particularly useful for the types of memories shown. FIGS. 6 through 8 show crystal structures of several exemplary classes of ferroelectric materials that can be utilized with the invention. However, it should be understood that the invention is not limited to these specific classes of ferroelectrics or particular materials within these classes. The invention may be applied to any ferroelectric material, though it is particularly useful for the classes of materials and the specific materials discussed herein.

FIG. 1 shows a portion of a raw ferroelectric array 10. Raw array 10 is formed on a substrate 15, which is preferably silicon or silicon oxide, though it also may be ruby, germanium, silicon-germanium, other semiconductors, or any other suitable electronic substrate material. An optional barrier layer 17, such as tantalum oxide, silicon nitride, strontium tantalate or other barrier material may be applied to the substrate 15. Rows of lower electrodes 18 are formed on the substrate 15, preferably on the barrier layer 17. The electrodes are preferably formed by depositing a layer of platinum, preferably about 200 nanometers (nm) thick, though palladium, silver, gold, aluminum, an aluminum alloy, a nickel alloy, a copper alloy or other suitable material may be used. In addition, an adhesion layer (not shown) such as titanium is preferably used to enhance the adhesion of the electrodes to the underlying layers. A ferroelectric layer is deposited in a manner discussed below, then the ferroelectric and bottom electrodes are patterned with a dry etch to separate the platinum into strips. An interlayer dielectric 19, such a silicate glass, is applied between the electrodes and ferroelectric strips and planarized, preferably by CMP. Preferably, interlayer dielectric 19 comprises NSG (non-doped silicate glass), though FSG (fluorosilicate glass), PSG, phospho-silicate glass, or BPSG (boron phospho-silicate glass may be used. Top electrodes 26 are then deposited, again preferably about 2000 nm of platinum or other material, and then the top electrodes and ferroelectric are patterned an additional interlayer dielectric 27 is applied. Vias are then etched to the electrodes 17 and 26 and filled with a wiring material 29 and 30, which may be polysilicon but is preferably a metal, such as aluminum-silicon-copper. Preferably, an adhesion material, such as titanium and TiN, is deposited prior to the wiring layer to enhance the adhesion of the wiring layer to the platinum electrode.

FIG. 2 shows a variation of a raw array in which diodes, such as 44, 45, and 46 are placed in series with ferroelectric capacitors, such as 48, 49, and 50. Pulse sources 35, 36, 37 are applied to row electrodes while pulse sources 52, 53, and 54 are applied to column electrodes, with load resistors 40, 41, 42, 56, 57, and 58 connected to ground. This memory is described in detail in U.S. Pat. No. 2,876,436 issued to J. R. Anderson on Mar. 3, 1959, which patent is hereby incorporated by reference to the same extent as though fully disclosed herein.

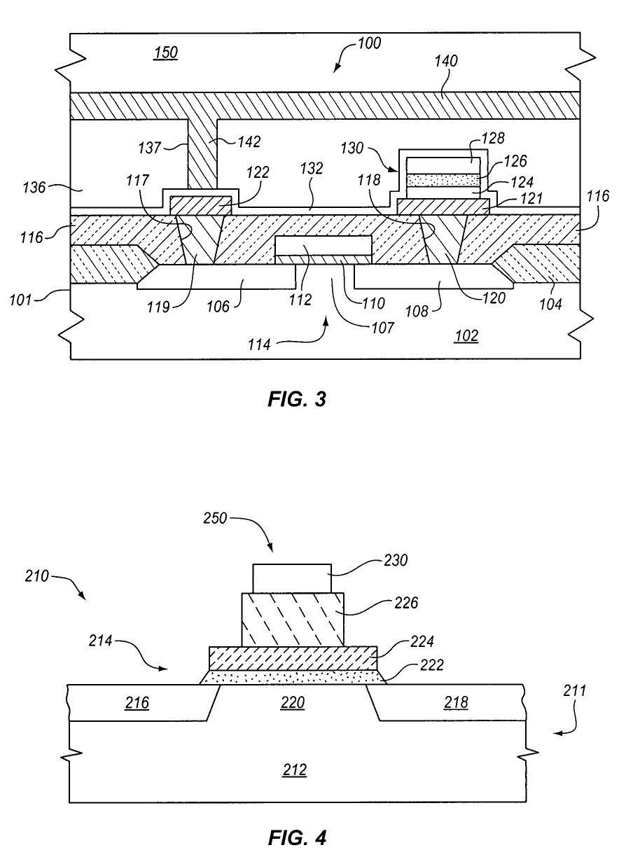

It should be understood that FIGS. 1, 3, and 4 depicting integrated circuit devices, are not meant to be actual plan or cross-sectional views of any particular portion of actual integrated circuit devices. In actual devices, the layers will not be as regular and the thickness may have different proportions. The various layers in actual devices often are curved and possess overlapping edges. The figures instead show idealized representations which are employed to explain more clearly and fully the method of the invention than would otherwise be possible. Also, the figures represent only one of innumerable variations of ferroelectric and dielectric devices that could be fabricated using the method of the invention. For example, FIG. 3 depicts a portion of a ferroelectric memory 100 containing a switch in the form of a field effect transistor 114 in electrical connection with a ferroelectric capacitor 130. Although the ferroelectric element 126 depicted in FIG. 3 is substantially above switch element 114, the invention is also useful, for example, to fabricate a thin film of layered superlattice material in a memory cell or other integrated circuit device disposed in a sideways or vertical orientation with respect to the horizontal plane of FIG. 3. In addition, a method in accordance with the invention may also be used to fabricate a ferroelectric FET memory in which the ferroelectric element comprising layered superlattice material is incorporated in the switch element. Such a ferroelectric FET, as depicted in FIG. 4, was described in U.S. Pat. No. 5,523,964 issued Jun. 4, 1996 to McMillan et al. and U.S. patent application Ser. No. 09/365,628 filed Aug. 2, 1999, which are hereby incorporated by reference as though fully disclosed herein.

FIG. 3 shows a cross-sectional view of an exemplary nonvolatile ferroelectric memory 100 fabricated in accordance with the invention. The general manufacturing steps for fabricating integrated circuits containing MOSFETs and ferroelectric capacitor elements are described in U.S. Pat. No. 5,466,629, issued Nov. 14, 1995 to Mihara et al., and U.S. Pat. No. 5,468,684, issued Nov. 21, 1995 to Yoshimori et al., which are hereby incorporated by reference as though fully disclosed herein. General fabrication methods have been described in other references also, and are well known in the art. Therefore, the elements of the circuit of FIG. 3 will be simply identified here.

FIG. 3 shows a ferroelectric random access memory cell 100. Memory cell 100 includes a transistor switch 114 and a capacitor 130 formed on a semiconductor wafer 101. In the embodiment shown, transistor 114 is a MOSFET and includes source region 106, drain region 108, a channel region 107, gate insulating layer 110 and gate electrode 112. Capacitor 130 includes bottom electrode 124, ferroelectric layer 126, and top electrode 128. A field oxide region 104 is formed on a surface of a silicon substrate 102. Source region 106 and drain region 108 are formed separately from each other within silicon substrate 102. A gate insulating layer 110 is formed on silicon substrate 102 between the source and drain regions 106 and 108. Further, a gate electrode 112 is formed on gate insulating layer 110.

A first interlayer dielectric layer (ILD) 116 made of BPSG (boron-doped phospho-silicate glass) is formed on substrate 102 and field oxide region 104. ILD 116 is patterned to form vias 117, 118 to source region 106 and drain region 108, respectively. Vias 117, 118 are filled to form plugs 119, 120, respectively. Plugs 119, 120 are electrically conductive and typically comprise tungsten or polycrystalline silicon. Diffusion barrier material is deposited and patterned on ILD 116 to form diffusion barriers 121, 122 in electrical contact with plugs 119, 120, respectively. Diffusion barriers 121, 122 are made of, for example, titanium nitride, and typically have a thickness of 10 nm to 20 nm. Diffusion barrier layers, such as titanium nitride, inhibit the diffusion of chemical species between the underlying and overlying layers of memory 100.

As depicted in FIG. 3, a bottom electrode layer 124 made of platinum and having a thickness of 100 nm is deposited on diffusion barrier layer 121. Then a ferroelectric thin film 126 of layered superlattice material is formed in accordance with the invention on bottom electrode layer 124. A top electrode layer 128, made of platinum and having a thickness of 100 nm, is formed on ferroelectric thin film 126.

Wafer substrate 102 may comprise silicon, gallium arsenide or other semiconductor, or an insulator, such as silicon dioxide, glass or magnesium oxide (MgO). The bottom and top electrodes of ferroelectric capacitors conventionally contain platinum. It is preferable that the bottom electrode contains a non-oxidized precious metal such as platinum, palladium, silver, and gold. In addition to the precious metal, metal such as aluminum, aluminum alloy, aluminum silicon, aluminum nickel, nickel alloy, copper alloy, and aluminum copper may be used for electrodes of a ferroelectric memory. Adhesive layers (not shown), such as titanium, enhance the adhesion of the electrodes to adjacent underlying or overlying layers of the circuits. Hydrogen barrier layer 132 is formed above ferroelectric capacitor 130 and MOSFET 114, to cover the surface area above memory cell 100. The composition, fabrication and etching of hydrogen barriers are known in the art. See, for example, U.S. Pat. No. 6,225,565 B1 issued May 1, 2001 to Cuchiaro et al., and U.S. Pat. No. 6,180,971 issued Jan. 30, 2001 to Maejima, which are hereby incorporated by reference.

A second interlayer dielectric layer (ILD) 136 made of NSG (non-doped silicate glass) is deposited to cover ILD 116, diffusion barrier layer 121, and ferroelectric capacitor 130. A doped silicate glass, such as FSG (fluorosilicate glass), PSG (phospho-silicate glass) film or a BPSG (boron phospho-silicate glass) film could also be used in layer 136. ILD 136 is patterned to form a via 137 through barrier 132 to plug 119. A metallized wiring film 140 is deposited to cover ILD 136 and fill via 137 and then patterned to form plug 137 and source electrode wiring 142. Top electrode wiring (not shown in cross-section) makes electrical connection to top plate-electrode 128. Wirings 140, 142 preferably comprise Al—Si—Cu standard interconnect metal with a thickness of about 200 nm to 300 nm. Typically, a film of adhesion material (not shown), for example, comprising Ti and TiN, is deposited on the substrate and wiring film 140 is then formed on the adhesion film. Dielectric layer 150 covers wiring film 140 and ILD 136.

FIG. 4 shows a cross-sectional view of a portion of a ferroelectric FET memory 210 as may be fabricated using a method in accordance with an embodiment of the invention. Memory 210 comprises a ferroelectric FET 250 formed on a wafer 211, comprising a standard semiconductor material 212, preferably a p-100 silicon material. A semiconductor substrate 214 comprises a highly doped source region 216 and a highly doped drain region 218, which are formed about a doped channel region 220. Doped source region 216, drain region 218 and channel region 220 are preferably n-type doped regions, but also may be p-type regions formed in an n-type semiconductor. Semiconductor substrate 214 typically also includes a gate oxide 222, usually located above channel region 220, but which can extend beyond channel region 220 to cover parts of source region 216, drain region 218 and other parts of semiconductor material 212. Typically, gate oxide 222 is formed from semiconductor material 212 during high temperature process steps. When semiconductor material 212 is silicon, then gate oxide 222 usually comprises silicon dioxide. An interface insulator layer 224 may be formed above semiconductor substrate 214 above channel 220, usually on gate oxide 222. A ferroelectric thin film 226, formed in accordance with the invention, is located above interface insulator layer 224 and channel region 218, usually on interface insulator layer 224. Gate electrode 230 is formed above ferroelectric thin film 226, usually on ferroelectric thin film 226.

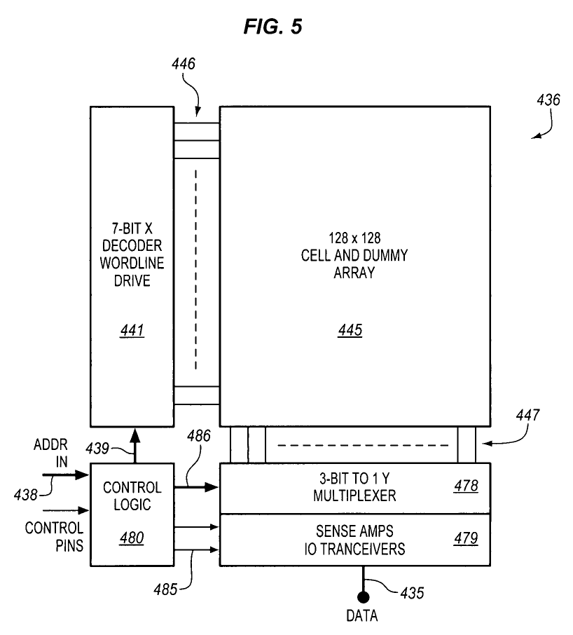

FIG. 5 is a block diagram illustrating an exemplary integrated circuit memory 436 in which the memory cells of FIGS. 3 and 4, and the memory arrays of FIGS. 1 and 2 according to the invention are utilized. For simplicity, the embodiment shown is for a 16K×1 FeRAM; however, the invention may be utilized in a wide variety of sizes and types of memories, including, but not limited to, those in which the addresses are not multiplexed, such as flash or SRAM type memories. In the 16K embodiment shown, there are seven address input lines 438 which connect through Control Logic section 480 and lines 439 to the X decode section 441. X decoder 441 is connected to a 128×128 memory cell array 445 via 128 lines 446, which comprise the word lines, such as 112 (FIG. 3), or drive lines, 80, 81, and 82 (FIG. 2), and 26 (FIG. 1). Three other address lines 438 are decoded via Control Logic 480 to generate 8 Y select lines 486 to drive Y multiplexer 478, which drives the bit and drive lines 140, 128 (FIG. 3), 230 (FIG. 4), 90, 91, and 92 (FIG. 2) and 18 (FIG. 1). Control Logic signal generator 480 is connected to the sense amplifier and data-out multiplexer circuit 479 via lines 485. These lines provide the control signals for the memories, which will be different for each of the different memories, but the structure and operation of which is known in the art. The number of lines 446, 447, 485 and 486 depends on which embodiment of the invention discussed herein is utilized, as well as the size of the array. DATA bus 435 is a bi-directional sixteen bit bus connected to the sense amplifier and data-out multiplexer 479 and providing a sixteen bit data input into the memory. The embodiment of the memory cell array 445 shown contains 128×128=16,384 memory cells, which is conventionally designated as 16K. These cells are ferroelectric switching capacitor-based cells such as 33 (FIG. 1), 93 (FIG. 2), 100 (FIG. 3), and 250 (FIG. 4).

The operation of the memory in FIG. 5 is as follows. X Decoder signals A₀ through A₆ and Y Decoder signals A₇ through A₉ are latched, buffered, and decoded y Control Logic 480 and passed to X decoder 441 and two-way Y multiplexer 478, respectively. X decoder 441 decodes the address signals and places the word line signals, such as the WL0 and WL1 signals discussed above, on one of word lines 446; generally a signal is placed on the word line of the cell that is addressed. The Sense Amplifiers and IO Transceiver circuit 479 includes sense amplifiers, which are located along lines 447 to sense and amplify the signals on the selected lines, and the IO transceiver in circuit 479 drives and receives data from data line 435.

The various components of memory 436 in FIG. 5 are shown only as an exemplary embodiment to illustrate how the invention is used. However, there are literally hundreds of memory designs in which the invention may be used, and different designs place the various components in different locations, may not use some of the components, or may use other components. For example, in different memory designs, the sense amplifiers are placed at the midpoint of lines 447, at the same end as the line drivers, or some other place in the circuit. In some memories, signal generator 480 and X decoder and word line driver circuit may be combined into a single signal generation unit. The circuitry of the various components of memory 436, except as discussed elsewhere herein, is known in the art of integrated circuit memory design, and will not be further discussed herein. Other logic required or useful to carry out the functions outlined above, as well as other known memory functions, is also included in memory 436 but is not shown or discussed, as it is not directly applicable to the invention.

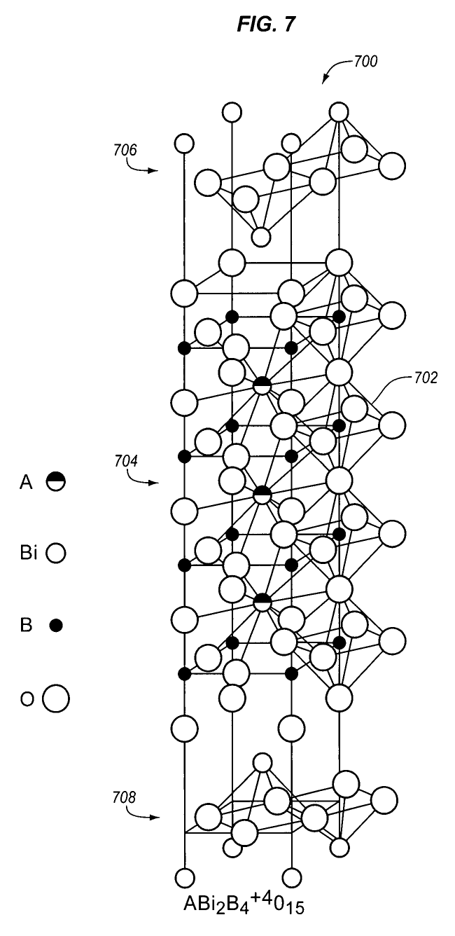

Turning now to FIG. 6 a layered superlattice material 600 is illustrated. The layered superlattice materials spontaneously form into layers 604 with a perovskite-like structure which alternate with layers 606 having a simpler structure. Depending on the material, the perovskite-like layers 604 may include one or a plurality of linked layers of perovskite-like octahedrons 602. As an example, FIG. 6 shows a unit cell of the material having the formula ABi₂B₂⁺⁵O₉, which is the formula for strontium bismuth tantalate (SrBi₂Ta₂O₉) and others layered superlattice materials, such as tantalum, niobium, and tungsten, having a element with a valence of +5 in the B-site. In this structure, each perovskite-like layer 604 includes two layers of octahedrons 602 which are separated by layers 606 of a material that does not have a perovskite-like structure. In this material the primitive unit cell consists of two perovskite-like layers 604 and two non-perovskite-like layers 606, since the structure shifts between the layers 610 and 612. FIG. 7 shows the crystal structure for a layered superlattice material having the formula ABi₂B₄⁺⁴O₁₅, which is the formula for strontium bismuth titanate (SrBi₂Ti₄O₁₅) and other layered superlattice materials having an element, such as titanium, hafnium, and zirconium having a valence of +4 in the B-sites. Again, the layered structure comprises perovskite-like layers 704 alternating with simple oxide layers 706. In this material, each perovskite-like layer 704 has four layers of octahedrons 702.

U.S. Pat. No. 5,519,234 issued May 21, 1996 to Paz de Araujo et al. discloses that layered superlattice compounds, such as strontium bismuth tantalate, have excellent properties in ferroelectric applications as compared to the best prior materials and have high dielectric constants and low leakage currents. U.S. Pat. No. 5,434,102 issued Jul. 18, 1995 to Watanabe et al. and U.S. Pat. No. 5,468,684 issued Nov. 21, 1995 to Yoshimori et al. describe processes for integrating these materials into practical integrated circuits.

The layered superlattice materials may be summarized generally under the formula:

A1_{w1}^{+a1}A2_{w2}^{+a2} . . . Aj_{wj}^{+aj}S1ₓ₁^{+s1}S2ₓ₂^{+S2} . . . Skₓₖ^{+sk}B1_{y1}^{+b1}B2_{y2}^{+b2} . . . Bl_{yl}^{+bl}Q_{z}^{-q} (1)

where A1, A2 . . . Aj represent A-site elements in the perovskite-like structure, which may be elements such as strontium, calcium, barium, bismuth, lead, and others; S1, S2 . . . Sk represent superlattice generator elements, which usually is bismuth, but can also be materials such as yttrium, scandium, lanthanum, antimony, chromium, thallium, and other elements with a valence of +3; B1, B2 . . . Bl represent B-site elements in the perovskite-like structure, which may be elements such as titanium, tantalum, hafnium, tungsten, niobium, zirconium, and other elements; and Q represents an anion, which generally is oxygen but may also be other elements, such as fluorine, chlorine and hybrids of these elements, such as the oxyfluorides, the oxychlorides, etc. The superscripts in Formula (1) indicate the valences of the respective elements; for example, if Q is oxygen, then q=2. The subscripts indicate the number of moles of the material in a mole of the compound, or in terms of the unit cell, the number of atoms of the element, on the average, in the unit cell. The subscripts can be integer or fractional. That is, Formula (1) includes the cases where the unit cell may vary uniformly throughout the material; for example, in SrBi₂(Ta_{0.75}Nb_{0.25})₂O₉, 75% of the B-sites are occupied by strontium atoms, and 25% of the B-sites are occupied by barium atoms. If there is only one A-site element in the compound, then it is represented by the “A1” element and w2 . . . wj all equal zero. If there is only one B-site element in the compound, then it is represented by the “B1” element, and y2 . . . yl all equal zero, and similarly for the superlattice generator elements. The usual case is that there is one A-site element, one superlattice generator element, and one or two B-site elements, although Formula (1) is written in the more general form since the invention is intended to include cases where either of the sites and the superlattice generator can have multiple elements. The value of z is found from the equation:

(a1w1+a2w2 . . . +ajwj)+(s1x1+s2x2 . . . +skxk)+(b1y1+b2y2 . . . +blyl)=qz. (2)

Formula (1) includes all three of the Smolenskii type compounds discussed in U.S. Pat. No. 5,519,234 issued May 21, 1996 to Paz de Araujo et al., referenced above. The layered superlattice materials do not include every material that can be fit into Formula (1), but only those which form crystalline structures with distinct alternating layers upon heating.

U.S. Pat. No. 5,803,961 issued Sep. 8, 1998 to Azuma et al. discloses that mixed layered superlattice materials, such as strontium bismuth tantalum niobate, can have even more improved properties in ferroelectric applications. The mixed layered superlattice materials are typically characterized by nonstoichiometric amounts of A-site and B-site elements. For example, a preferred precursor used in accordance with the invention comprises metal organic precursor compounds having metals in relative molar proportions corresponding to the stoichiometrically unbalanced formula Sr_{0.8}Bi₂(Ta_{0.7}Nb_{0.3})₂O_{8.8}.

Currently, ferroelectric layered superlattice materials, like the metal oxides SrBi₂Ta₂O₉ (SBT), SrBi₂(Ta₁₋ₓNbₓ)₂O₉ (SBTN), where 0<x<1, and particularly SrₐBi_{b}(Ta₁₋ₓNbₓ)_{c}O_{[9+(a-1)+(b-2)(1.5)+(c-2)(2.5)]}, where 0.7≦a≦1, 2≦b≦2.2, 0≦x≦0.3 and 1.9≦c≦2.1 (SBTN), are being used and are under further development for use as a capacitor dielectric in nonvolatile memory applications, such as in FeRAMs and nondestructible read-out ferroelectric FETs. Polycrystalline thin films of these layered superlattice materials, as well as other layered superlattice materials represented by Formula (1), may be fabricated and used in accordance with the invention.

Methods in accordance with the present invention are also generally useful for fabrication of integrated circuits containing metal oxide thin films, including but not limited to, ABO₃-type perovskite metal oxides. In the general formula ABO₃, A and B are cations and O is the anion oxygen. The term is intended to include materials where A and B represent multiple elements; for example, it includes materials of the form A′A″BO₃, AB′B″O₃, and A′A″B′B″O₃, where A′, A″, B′ and B″ are different metal elements. Preferably, A, A′, A″, are metals selected from the group of metals consisting of Ba, Bi, Sr, Pb, Ca, and La, and B, B′, and B″ are metals selected from the group consisting of Ti, Zr, Ta, Mo, W, and Nb. A, A′, and A″ are collectively referred to herein as A-site materials. B, B′, and B″ are collectively referred to herein as B-site materials. Some perovskite metal oxides, such as PZT and PLZT, are classified as ferroelectrics, though some may not exhibit ferroelectricity at room temperature. Others do not exhibit ferroelectric properties, but have high dielectric constants and are useful in high dielectric constant capacitors. For example, barium strontium titanate (“BST”) and other ABO₃-type perovskite metal oxides, are used as capacitor dielectric in DRAMs. Preferably, BST is fabricated in accordance with the invention by blending excess A-site and B-site materials in a BST-precursor solution, as described in U.S. Pat. No. 6,025,619, issued Feb. 15, 2000, to Azuma et al., which is hereby incorporated by reference. The excess A-site and B-site materials increase the dielectric constant of the dielectric layer of the capacitor with little or no effect on leakage current.

An RTP operation in accordance with the invention is generally conducted in a conventional rapid thermal processing apparatus. In accordance with the invention, an initial RTP operation is generally at least partially conducted in an oxygen-containing atmosphere to enhance formation of the metal oxide bonds in polycrystalline layered superlattice materials and other ferroelectric or dielectric compounds. It is contemplated, however, that an oxygen-free unreactive atmosphere may be used for a significant part of the holding time.

A method in accordance with the invention includes rapidly ramping the temperature in the oven of an RTP apparatus up to the hold temperature. It is contemplated, however, that a plurality of hold temperatures may be used. As a result of the RTP, the annealing of the layered superlattice material, or other dielectric or ferroelectric metal oxide, occurs substantially at the hold temperature, rather than the lower temperature region. That is, it is believed that by using RTP, the crystallization process proceeds directly into the high temperature crystalline phase, thus reducing or eliminating altogether the generation of the low temperature crystalline phases, which are referred to in the art as the “fluorite phases”. The actual ramping rate is typically in the range of from 10° C. to 150° C. per second, preferably about 100° C. per second. The term “ramp rate” applies to the rate of temperature increase experienced in the integrated circuit substrate. Typically, the hold temperature is the maximum temperature reached during the RTP. After annealing at the RTP hold temperature, the substrate may be cooled using conventional cooling techniques.

The word “substrate” can mean the underlying semiconductor material 102, 212 on which the integrated circuit is formed, as well as any object on which a thin film layer is deposited. In this disclosure, “substrate” shall generally mean the object to which the layer of interest is applied. For example, when we are talking about a ferroelectric thin film 126 of FIG. 3, the substrate on which it is initially deposited may include various elements, in particular, bottom electrode 124. In terms of FIG. 4, the substrate may by 212 when talking about the oxide layer 222, but will be 214 when talking of the layer 224.

The long horizontal dimensions of substrates 15, 102, 212 define planes that are considered to be a “horizontal” plane herein, and directions perpendicular to this plane are considered to be “vertical”. The terms “lateral” or “laterally” refer to the direction of the flat plane of the semiconductor substrate, that is, parallel to the horizontal direction. Terms of orientation herein, such as “above”, “top”, “upper”, “below”, “bottom” and “lower”, mean relative to substrate 15, 102, 212. That is, if a second element is “above” a first element, it means it is farther from semiconductor substrate 102, 212; and if it is “below” another element, then it is closer to semiconductor substrate 102, 212xx than the other element. Terms such as “above” and “below” do not, by themselves, signify direct contact. However, terms such as “on” or “onto” do signify direct contact of one layer with an underlying layer. It is understood that thin films of layered superlattice material fabricated in accordance with the invention have various shapes and conform to various topographies and features of an integrated circuit substrate. Accordingly, thin films of ferroelectric or other metal oxide material in accordance with the invention are formed on planar substrates, in trenches and vias, on vertical sidewalls, and in other various non-horizontal and three-dimensional shapes.

The term “thin film” is used herein as it is used in the integrated circuit art. Generally, it means a film of less than a micron in thickness. The thin films disclosed herein are typically less than 500 nm in thickness. A thin film of layered superlattice material fabricated by a method in accordance with the invention typically has a final thickness in a range of about from 10 nm to 300 nm, preferably in a range of about from 15 nm to 150 nm, but can be less. The thin films having a thickness of about 50 nm or less are sometimes designated “ultra-thin films” in this specification. Generally, the term “thin film” includes ultra-thin films. These thin films and ultra-thin films of the integrated circuit art should not be confused with the layered capacitors of the macroscopic capacitor art which are formed by a wholly different process that is incompatible with the integrated circuit art.

The term “stoichiometric” herein may be applied to both a solid film of a material, such as a layered superlattice material, or to the precursor for forming a material. When it is applied to a solid thin film, it refers to a formula which shows the actual relative amounts of each element in a final solid thin film. When applied to a precursor, it indicates the molar proportion of metal atoms in the precursor. A “balanced” stoichiometric formula is one in which there is just enough of each element to form a complete crystal structure of the material with all sites of the crystal lattice occupied, though in actual practice there always will be some defects in the crystal at room temperature. For example, both SrBi₂(TaNb)O₉ and SrBi₂(Ta_{1.5}Nb_{0.5})O₉ are balanced stoichiometric formulae. In contrast, a precursor for strontium bismuth tantalum niobate in which the molar proportions of strontium, bismuth, tantalum, and niobium are 0.9, 2.18, 1.5, and 0.5, respectively, is represented herein by the unbalanced “stoichiometric” formula Sr_{0.9}Bi_{2.18}(Ta_{1.5}Nb_{0.5})O₉, since it contains excess bismuth and deficient strontium relative to the B-site elements tantalum and niobium. It is common in the art to write an unbalanced stoichiometric formula of a metal oxide in which the subscript of the oxygen symbol is not corrected to balance completely the subscript values of the metals.

The word “precursor” used herein can mean a solution containing one metal organic solute that is mixed with other precursors to form intermediate precursors or final precursors, or it may refer to a final liquid precursor solution or gas mixture, that is, the precursor to be applied to a particular surface during fabrication. The precursor as applied to the substrate is usually referred to as the “final precursor”, “precursor mixture”, or simply “precursor”. In any case, the meaning is clear from the context.

A “precursor compound” or “precursor” in this disclosure refers both to a metal organic compound containing at least one metal that is included in the desired layered superlattice material of the thin film formed in accordance with the invention and to the compound, such as H₂O, which is used to add the non-metal, such a oxygen, in the ferroelectric material.

Turning to FIG. 9, there is shown an exemplary atomic layer deposition process according to the invention. This process is for the preferred ferroelectric, a three-metal layered superlattice material such as strontium bismuth tantalate or niobium bismuth tantalate. At 902 the precursors are prepared. A feature of the invention is that many different possible precursors may be used. For example, when forming the layered superlattice material strontium bismuth tantalate, precursors can include methoxides, i.e., Ta(OCH₃)₅, Bi(OCH₃)₃, and Sr(OCH₃)₂, butoxides, i.e., Ta(OC₄H₉)₅, Bi(OC₄H₉)₃, and Sr(OC₄H₉)₂, ethoxides, i.e., Ta(OC₂H₅)₅, Bi(OC₂H₅)₃, and Sr(OC₂H₅)₂, or propoxides, i.e., Ta(OC₃H₇)₅, Bi(OC₃H₇)₃, and Sr(OC₃H₇)₂. Although precursors of the same families, e.g. methoxides, butoxides, etc., are included together in the above summary, this is not necessary. Sometimes the use of a methoxide, for example, for one metal and the use of a propoxide, for example, for another metal gives better results. Typical chemistry families that may be used as precursors are the alkoxides which include: methoxide [M(OCH₃)ₙ], ethoxide [M(OC₂H₅)ₙ], propoxide [M(OC₃H₇)ₙ], and butoxide [M(OC₄H₉)ₙ], where M is a metal and n is the number of alkoxyl bases combining with the metal and is equal to the valence of the metal. A polymerized alkoxide can also be used for the CVD source. A preferable length of the alkoxide polymer chain is between 1 and 5 monomer units. Other chemistry families that may be used are the beta-diketonates such as acetylacetonate with the formula:

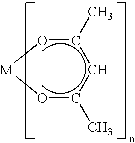

where M represents metal and n represents the number of monomers, and benzoilacetonate with the formula:

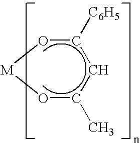

As indicated above the perovskites and layered superlattice materials may include metals such as strontium, calcium, barium, bismuth, cadmium, lead, titanium, tantalum, hafnium, tungsten, niobium zirconium, bismuth, scandium, yttrium, lanthanum and the lanthanides, antimony, chromium, molybdenum, vanadium, ruthenium and thallium. Some examples of precursors that may be used for some of these metals are given in Table 1.

TABLE 1

| METAL | PRECURSOR FORMULA |
|---|---|
| Strontium | Sr(DPM)₂ |
| | Sr(Cp)₂(THF)₂ |
| | Sr(DPM)₂(Phen)₂ |
| Bismuth | BiPh₃ |
| | Bi (OiPr)₃ |
| | Bi(DPM)₃ |
| Barium | Ba(DPM)₂ |
| | Ba(DPM)₂.tetraglyme |
| | Ba(fod)₂ |
| | Ba(methylcyclopentadienyl)₂.(THF) |
| | Ba(DPM)₂.NR₃ |
| | Ba(hfac)₂ |
| | Ba(hfac)₂.tetraglyme |
| Lead | Pb(DPM)₂ |
| | Pb(C₂H₅)₂ |
| Tantalum | Ta(OCH₃)₅ |
| | Ta(OC₂H₅)₅ |
| | Ta(OC₃H₇)₅ |
| | TaCl₅ |
| Niobium | Nb(OC₂H₅)₅ |
| | NbCl₅ |
| | Nb(DPM)₂Cl₃ |
| Antimony | Sb(OC₂H₅)₃ |
| Titanium | Ti(OiPr)₂(DPM)₂ |
| | Ti(OiPr)₄ |
| Zirconium | Zr(DPM)₄ |
| Ruthenium | Ru(DPM)₃ |
| Calcium | Ca(DPM)₄ |
| | Ca(DPM)₂.tetraethylenepentamine |
| | Ca(fod)₂ |

In Table I, DPM is C₁₁H₁₉O₂ usually called 2,2,6,6,-tetramethyl-3,5-heptanedione, fod is 6,67,7,8,8,8-heptafluor-2,2,-dimethyl-3,5-octanedioneate, and hfac is 1,1,1,5,5,-hexafluoro-2,4-pentanedioneate. Other compounds of the metals that may be used include compounds with 2,4-pentadione and compounds with 1,3-perfluoropropyl-1,3-propanedionate. From the above, those skilled in the art will be able to derive other useful precursor compounds.

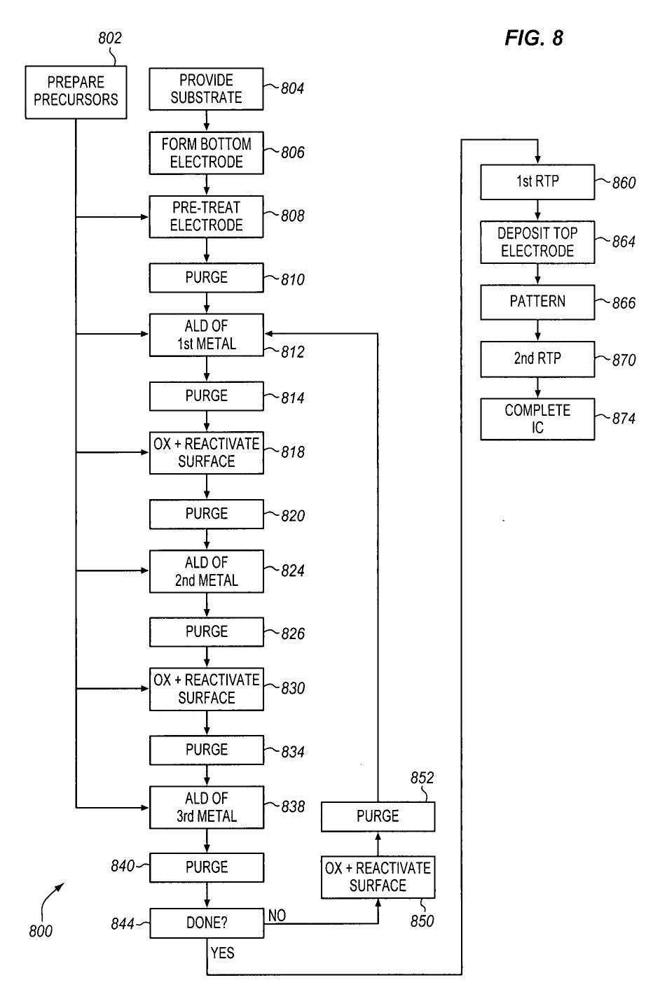

Returning to FIG. 8, a substrate is provided at 804. As discussed above, this may be a simple wafer of silicon, gallium arsenide, germanium, silicon germanium, silicon dioxide, ruby, or other material, a complex substrate with transistors and other circuitry already formed in it, or any other subject on which it is desired to deposit the layered superlattice material. A bottom electrode is formed at 806, preferably of one of the metals described above, such as platinum, and preferably with an adhesion layer. Such electrodes are well-known in the art. Process 808 is a pretreatment process such as described in United States Patent Publication No. 2003/0027431 and United States Patent Publication No. 2003/0168001, which are hereby incorporated by reference to the same extent as though fully disclosed herein. The purpose of this process is to create more reaction sites for the ALD precursor to react with. Process 808 is optional, but if it is performed, a purge process 810 should follow to clear the ALD reactor. In process 812, the atomic layer deposition of the first metal takes place. The first metal may be any of the three metals in a three-metal layered superlattice material, but preferably is the superlattice generator element, such as bismuth.

The ALD processes 812, 824, and 838 are preferably performed using an ALD apparatus as described in U.S. Pat. No. 6,911,092 issued Jun. 28, 2005 and CRISP oxidation/surface activation cycles 818,830, and 850 as described in United States Published Patent Application No. 2003/0168001, which foregoing patent and patent application are hereby incorporated by reference to the same extent as though fully disclosed herein.

After ALD of the first metal the system is purged at 814, then at 818 the non-metal element is deposited. Generally, the non-metal element is oxygen, but it also can be other elements, such as fluorine, chlorine and hybids of these elements, such as oxyfluorides, oxychlorides, etc. If the non-metal element is oxygen, the precursor is preferably H₂O, but can also be O₂, O₃, N₂O or H₂O₂. At 820 the non-metal precursor is purged, and at 824 the second metal is deposited by ALD. The second metal can be either of the remaining metals. The precursors are given above. After deposition of the second metal, the second metal precursor is purged at 826 and then the non-metal element is again applied at 830 followed by a purge at 834. The third metal is then deposited by ALD at 838, followed by a purge of the third metal precursor at 840. If the desired thickness has not been reached, the process of applying the non-metal and reactivating the surface to receive a metal is repeated via 844, 846 and 850, followed by a purge at 852 and then processes 812 through 840 are repeated until the desired thickness has been deposited, at which time the flow branches at 844 to 860 via 848.

At 860, the deposited layered superlattice material is annealed in a first of pre-top-electrode anneal. The preferred anneal is via rapid thermal annealing (RTP) with a steep ramping rate and short hold. Preferably, the ramping rate is between 50° C. per second and 200° C. per second and more preferably between 90° C. per second and 150° C. per second. Preferably, the hold temperature is between 500° C. and 800° C. for a time period of from 0.5 seconds to 5 minutes, and more preferably, between 550° C. and 700° C. for 1 second to 30 seconds. The anneals are performed in oxygen, but also may be performed in an inert atmosphere, such as nitrogen or argon. The top electrode is deposited at 864, preferably of platinum as described above, and then at 886 the capacitor, including the bottom electrode, the layered superlattice material, and the top electrode are patterned at 866, preferably with a dry etch. Then follows a second or post-top-electrode RTP process 870, which is again short. In some cases, only one of the two RTP anneals will be performed, that is, one of the two RTP processes, preferably process 864, is optional. The integrated circuit is then completed at 874 with conventional wiring, usually including an adhesion layer, and passivation.

FIG. 9 is a top view of an exemplary wafer 900 on which thin film capacitors 905, 906 and 907 fabricated on substrate 912 in accordance with the invention are shown greatly enlarged. FIG. 10 is a portion of a cross-section 925 of FIG. 9 taken through the lines 10-10, illustrating thin film capacitor 905 fabricated in accordance with the invention. Section 925 includes a silicon dioxide layer 935 formed on a silicon wafer 930. Bottom electrode 940 made of platinum then is sputter-deposited on layer 935. A ferroelectric thin film 950 is made by ALD, and a sputtered platinum top electrode 960 completes the capacitor 905.

As an example of the preferred process, a P-type silicon wafer 930 is oxidized to form a layer of silicon dioxide 935. The substrate 936 is dehydrated in a vacuum oven at 180° C. for 30 minutes. A bottom platinum electrode 940 layer having a thickness of 200 nm is sputter-deposited on the substrate 936, using an argon atmosphere, 8 mTorr pressure and 0.53 amps. On each wafer, the bottom electrode layer is pre-annealed at 650° C. for 30 minutes in O₂ gas flowing at 6 l/m, using 10 minute push-pull. A dehydration bake was conducted in a vacuum oven at 180° C. for 30 minutes.

Strontium bismuth tantalate (SBT) thin films can be fabricated using triphenyl bismuth (BiPh₃) as the bismuth precursor, dipivaloylmethanato strontium (Sr[DPM]₂ as the strontium precursor, and pentaethoxy tantalum (TA[OEt]₅) as the tantalum precursor, at a deposition temperature of 125° C., and CRISP cycles as described in US 2003/0168001, at 80° C. for providing the oxygen and reactivation of the surface. The substrate is pre-TE RTP-treated at 650° C. for 30 seconds in O₂ gas, with a ramping rate of 100° C. per second to produce an SPT thin film approximately 20 nm thick. Next, platinum is sputter-deposited on the SBT thin film to make a top electrode layer 512 having a thickness of about 200 nm. The top electrode and SBT layers are milled (dry etch) to form capacitors, and then ashed. Post-TE RTP 870 is at a hold temperature of 750° C. for 50 seconds in O₂ gas, with a ramping rate of 100° C. per second.

It is a feature of the invention that the deposition cycles are performed without the temperature rising above 150° C., and the anneal cycles are very short, with a total anneal time of less than a few minutes, and preferably less than two minutes. This overcomes a major hurdle which has hindered progress in ferroelectric layered superlattice material memories, namely the high temperatures that had to be used to make the layered superlattice ferroelectrics and dielectrics in prior art methods. The high temperature of the prior art methods required elaborate measures to be taken to protect the other portions of the integrated circuit, such as the transistors. The high temperatures of the deposition processes, in which oxygen is necessary to be present, resulted in damage to the silicon semiconductors required in the circuit, which either shortened the overall circuit performance and life, or required a lengthy hydrogen backend process, which would cause oxygen defects in the ferroelectric material, which deteriorated the performance and the susceptibility to disturb.

Another feature of the invention is that in the preferred ALD processes, the cycles in which oxygen is present alternate with cycles in which hydrogen is present, and each oxygen and hydrogen cycle is extremely short, generally thirty seconds or less, more preferably five seconds or less, and most preferably a second or less. This compares to cycle time periods of ten minutes or more for oxygen and hydrogen exposure in the prior art. These rapid cycles provide little time for damage to the silicon or layered superlattice materials to occur. Moreover, since the oxygen and hydrogen cycles alternate, whatever damage that does occur, is immediately healed in the next portion of the cycle. This significantly reduces the defects in the ferroelectric, which leads directly to reduced disturb and more boxy polarizability curves.

A further feature of the invention is that, for the first time it makes possible high quality, low defect, polycrystalline thin films of layered superlattice ferroelectrics and dielectrics of a thickness of 50 nm and less, more preferably 30 nanometers or less, and most preferably of 20 nanometers and less. The ultra-thin, high quality ferroelectric and dielectric films that are made in the process of the invention, makes the simple memory as shown in FIGS. 1 and 2 possible.

There has been described a novel process for making layered superlattice ferroelectric materials and integrated circuits, particularly integrated circuit memories utilizing these materials. Now that the process and architecture has been described, those skilled in the art may make many variations. It should be understood that the particular embodiments shown in the drawings and described within this specification are for purposes of example and should not be construed to limit the invention, which will be described in the claims below. For example, if the array of FIG. 1 is turned ninety degrees, rows become columns and columns become rows. Further, word lines may be formed parallel to columns instead of rows, and bit lines may be formed parallel to rows instead of columns. Folded architectures known in the art may be employed. It is also evident that those skilled in the art may now make numerous uses and modifications of the specific embodiments described, without departing from the inventive concepts. It is further evident that the methods recited may, in many instances, be performed in a different order. Or equivalent components may be used in the sensors, and/or equivalent processes may be substituted for the various processes described. Consequently, the invention is to be construed as embracing each and every novel feature and novel combination of features present in and/or possessed by the invention herein described.

What is claimed is:

1. A method of making a ferroelectric integrated circuit, said method comprising:
depositing a thin film of a layered superlattice material using atomic layer deposition (ALD); and
completing said integrated circuit to incorporate said thin film as a component of said integrated circuit.

2. A method as in claim 1 wherein said layered superlattice material is a ferroelectric material.

3. A method as in claim 1 wherein said layered superlattice material is a dielectric material.

4. A method as in claim 1 and further comprising annealing said thin film using an RTP process.

5. A method as in claim 1 wherein said RTP process is performed at a temperature of between 500° C. and 800° C. for a time period of from 0.5 seconds to 5 minutes.

6. A method as in claim 1 wherein said RTP process is performed at a temperature between 550° C. and 700° C. for 1 second to 30 seconds.

7. A method as in claim 1 wherein said RTP process is performed with a ramping rate of between 50° C. per second and 200° C. per second.

8. A method as in claim 1 wherein said RTP process is performed with a ramping rate of between 90° C. per second and 150° C. per second.

9. A method as in claim 1 wherein said ALD process is performed with a plurality of alternating oxygen and hydrogen cycle portions, with each said cycle portions being of a length of 5 seconds or less.

10. A method as in claim 1 wherein each of said plurality of cycle portions is of a length of one second or less.

11. A method as in claim 1 wherein said ALD process is performed at a temperature of 150° C. or less.

12. A method as in claim 9 wherein said oxygen cycle portions are performed at a temperature of 150° C. or less and said hydrogen cycles are performed at a temperature of 100° C. or less.
